(19) United States
(12) Patent Application Publication
(10) Pub. No.: US 2015/0171056 A1
(43) Pub. Date: Jun. 18, 2015

(54) MANUFACTURING METHOD OF SEMICONDUCTOR DEVICE

(71) Applicant: Kabushiki Kaisha Toshiba, Minato-ku (JP)

(72) Inventors: Yoshiaki Goto, Kiyosu (JP); Takashi Imoto, Kamakura (JP); Takeshi Watanabe, Yokkaichi (JP); Yuusuke Takano, Yokkaichi (JP); Yusuke Akada, Mie (JP); Yuji Karakane, Nagoya (JP); Yoshinori Okayama, Yokohama (JP); Akihiko Yanagida, Zama (JP)

(73) Assignee: KABUSHIKI KAISHA TOSHIBA, Minato-ku (JP)

(21) Appl. No.: 14/482,574

(22) Filed: Sep. 10, 2014

(30) Foreign Application Priority Data
Dec. 13, 2013 (JP) 2013-258702

(51) Int. Cl. H01L 25/065; H01L 21/56; H01L 23/60

(52) U.S. Cl. CPC H01L 25/0655; H01L 23/60; H01L 21/561

(57) ABSTRACT

In a manufacturing method of a semiconductor device of an embodiment, a plurality of semiconductor packages, as objects to be processed, each including a semiconductor chip mounted on a wiring board and a sealing resin layer, and a tray including a plurality of housing parts are prepared. The semiconductor packages are respectively disposed in the plurality of housing parts of the tray. A metal material is sputtered on the semiconductor packages disposed in the housing parts, to thereby form a conductive shield layer covering an upper surface and side surfaces of each of the sealing resin layers and at least a part of side surfaces of each of the wiring boards.

### CROSS REFERENCE TO RELATED APPLICATION

This application is based upon and claims the benefit of priority from Japanese Patent Application No. 2013-258702, filed on Dec. 13, 2013; the entire contents of which are incorporated herein by reference.

### FIELD

Embodiments described herein relate generally to a manufacturing method of a semiconductor device.

### BACKGROUND

In a semiconductor device used in a communication device and the like, a structure in which a package surface is covered by a conductive shield layer is used to suppress an electromagnetic interference such as EMI (Electro Magnetic Interference). As a semiconductor device having a shielding function, there is known a structure having a conductive shield layer provided along an upper surface and side surfaces of a sealing resin layer which seals a semiconductor chip. In the formation of the conductive shield layer, a plating method, a sputtering method, a coating method of conductive paste, or the like is used. Among the methods of forming the conductive shield layer, the plating method has wet steps such as a pre-treatment step, a plating step, and a water-washing step, so that an increase in manufacturing cost of a semiconductor device is unavoidable. The coating method of conductive paste also easily causes the increase in manufacturing cost of the semiconductor device, since it includes a coating step with respect to side surfaces of a sealing resin layer.

The sputtering method includes dry steps, so that it is possible to reduce the number of steps of formation, a formation cost and the like of the conductive shield layer. When the sputtering method is applied to the formation of the conductive shield layer, it is considered to form the conductive shield layer before dividing the semiconductor packages into pieces. In such a case, semiconductor chips are first mounted on respective wiring board regions of a multi-cavity integrated board, and next, the plurality of semiconductor chips are collectively resin-sealed. Subsequently, the sealing resin layer and a part of the integrated board are cut to form a half-cut groove. The half-cut groove is formed to make a ground wiring line of the wiring board region to be exposed to side surfaces. By sputtering a metal material on the resin-sealed body having the half-cut groove, the conductive shield layer is formed. On side surfaces of the sealing resin layer and a part of side surfaces of the wiring board region, the metal material is sputtered via the half-cut groove.

A width of the half-cut groove is limited. For this reason, when the metal material is sputtered via the half-cut groove, there is a possibility that an adjacent package becomes an obstacle, and the side surfaces of the sealing resin layer and the wiring board region cannot be sufficiently covered by the conductive shield layer. If the side surfaces of the sealing resin layer and the wiring board region are covered by the conductive shield layer with a sufficient thickness, the metal material is thickly deposited on an upper surface of the sealing resin layer in which no obstacle exists. This becomes a main cause of increasing the formation cost of the conductive shield layer. Regarding the half-cut of the integrated board with a small thickness, it is difficult to control a depth of cut, and depending on circumstances, there is a possibility that the semiconductor packages are divided into pieces. From the circumstances as above, when forming the conductive shield layer on the package surface by applying the sputtering method, a technique of forming the conductive shield layer more securely and with a low cost, is required.

### BRIEF DESCRIPTION OF THE DRAWINGS

FIG. 1 is a top view illustrating a semiconductor device manufactured by a manufacturing method of an embodiment.

FIG. 2 is a sectional view of the semiconductor device illustrated in FIG. 1.

FIG. 3 is a sectional view illustrating a state before a conductive shield layer of the semiconductor device illustrated in FIG. 1 is formed.

FIG. 4 is a plan view illustrating a first example of a tray used in the manufacturing method of the embodiment.

FIG. 5 is a plan view illustrating, in an enlarged manner, a part of the tray illustrated in FIG. 4.

FIG. 6 is a sectional view taken along line A-A in FIG. 5.

FIG. 7A and FIG. 7B are sectional views illustrating manufacturing steps of the semiconductor device using the tray illustrated in FIG. 4 to FIG. 6.

FIG. 8 is a plan view illustrating, in an enlarged manner, a part of a second example of the tray used in the manufacturing method of the embodiment.

FIG. 9 is a sectional view taken along line A-A in FIG. 8.

FIG. 10 is a plan view illustrating a third example of the tray used in the manufacturing method of the embodiment.

FIG. 11 is a plan view illustrating, in an enlarged manner, a part of the tray illustrated in FIG. 10.

FIG. 12 is a sectional view taken along line A-A in FIG. 11.

FIG. 13 is a plan view illustrating, in an enlarged manner, a part of a fourth example of the tray used in the manufacturing method of the embodiment.

FIG. 14 is a sectional view taken along line A-A in FIG. 13.

FIG. 15 is a sectional view illustrating a state of formation of a sputtered film in a sputtering step using the tray illustrated in FIG. 13 and FIG. 14.

### DETAILED DESCRIPTION

According to one embodiment, there is provided a manufacturing method of a semiconductor device including: preparing a plurality of objects to be processed each having a wiring board, a semiconductor chip mounted on the wiring board, and a sealing resin layer sealing the semiconductor chip; preparing a tray having a plurality of housing parts; disposing, in each of the plurality of housing parts of the tray, the object so that an upper surface and side surfaces of the sealing resin layer and at least a part of side surfaces of the wiring board are exposed; and forming a conductive shield layer that covers the upper surface and the side surfaces of the sealing resin layer and at least a part of the side surfaces of the wiring board, by sputtering a metal material on the object disposed in each of the housing parts of the tray.

### (Semiconductor Device)

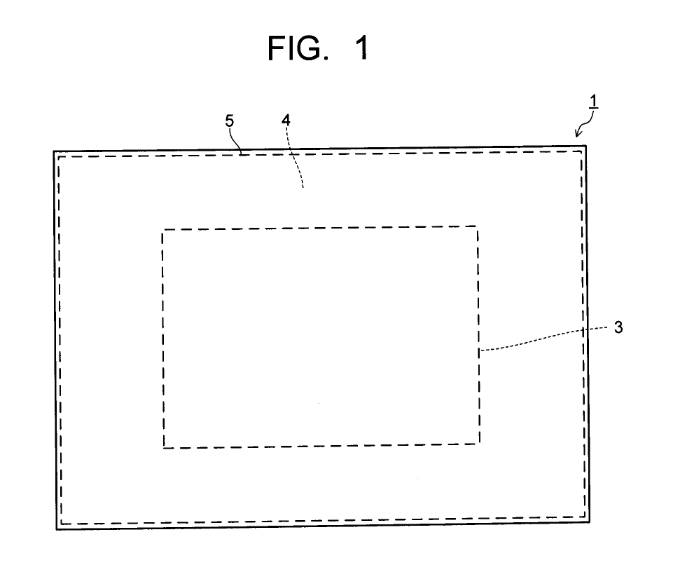

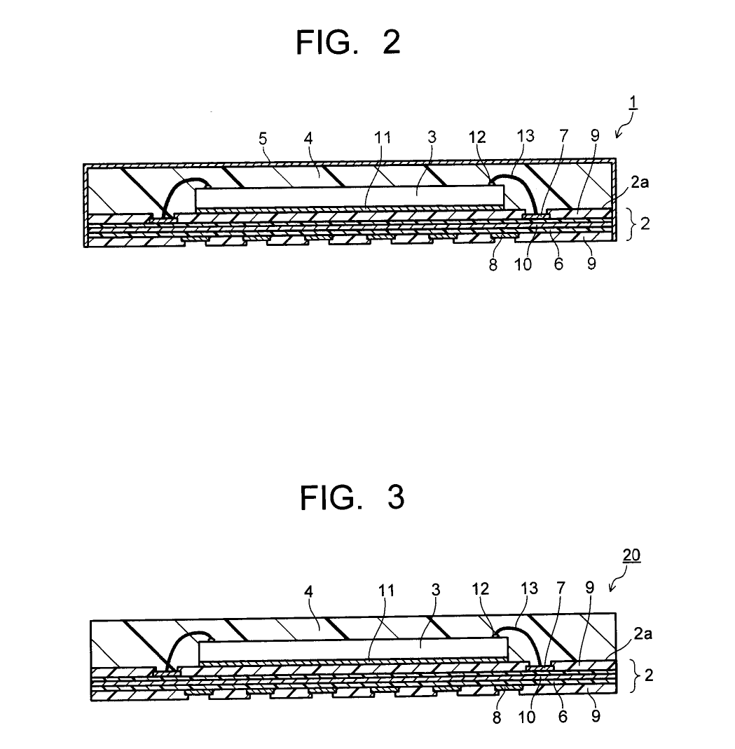

A semiconductor device manufactured by a manufacturing method of an embodiment will be described while referring to FIG. 1 and FIG. 2. FIG. 1 is a top view of the semiconductor device, and FIG. 2 is a sectional view of the semiconductor device. A semiconductor device 1 illustrated in these drawings is a semiconductor device with a shielding function including a wiring board 2, a semiconductor chip 3 mounted on a first surface 2a of the wiring board 2, a sealing resin layer 4 sealing the semiconductor chip 3, and a conductive shield layer 5 covering an upper surface and side surfaces of the sealing resin layer 4 and at least a part of side surfaces of the wiring board 2. Upper and lower directions as mentioned in the upper surface of the sealing resin layer 4 and so on are based on the case where the surface of the wiring board 2 on which the semiconductor chip 3 is mounted, is defined as the upper side.

The wiring board 2 has an insulating resin substrate as an insulating substrate 6. On an upper surface of the insulating substrate 6, a first wiring layer having internal connection terminals 7 to be electrical connection parts with the semiconductor chip 3 is provided. On a lower surface of the insulating substrate 6, a second wiring layer having external connection terminals 8 to be electrical connection parts with an external device is provided. On each of the first and second wiring layers, a solder resist layer 9 is formed. The wiring board 2 may also be a silicon interposer or the like. The first wiring layer and the second wiring layer are electrically connected through a via (not illustrated) provided so as to penetrate the insulating substrate 6, for example. A wiring network of the wiring board 2 including the first and second wiring layers and the via has a ground wiring line in which parts thereof are exposed to side surfaces of the insulating substrate 6.

In FIG. 2, a ground wiring line 10 in a state of solid film (or in a state of mesh film) formed inside of the insulating substrate 6 is illustrated. The ground wiring line 10 prevents a leakage of an unnecessary electromagnetic wave to the outside via the wiring board 2. End portions of the ground wiring line 10 are exposed to the side surfaces of the insulating substrate 6. Parts of the ground wiring line 10 exposed from the insulating substrate 6 become electrical connection parts with the conductive shield layer 5. The ground wiring line 10 in the state of solid film is illustrated, but the shape of the ground wiring line 10 is not limited to this. The ground wiring line which is exposed from the side surfaces of the insulating substrate 6 may also be a via. When the via as the ground wiring line is exposed from the side surfaces of the insulating substrate 6, it is preferable that, in order to increase an exposed area, at least part of the via are cut in a thickness direction of the insulating substrate 6, and the cut surface are exposed to the side surface of the insulating substrate 6.

On the first surface 2a of the wiring board 2, the semiconductor chip 3 is mounted. The semiconductor chip 3 is adhered to the first surface 2a of the wiring board 2 via an adhesive layer 11. Electrode pads 12 provided on an upper surface of the semiconductor chip 3 are electrically connected to the internal connection terminals 7 of the wiring board 2 via bonding wires 13 such as Au wires. Further, on the first surface 2a of the wiring board 2, the sealing resin layer 4 sealing the semiconductor chip 3 together with the bonding wires 13 is formed. The upper surface and the side surfaces of the sealing resin layer 4 and at least a part of the side surfaces of the wiring board 2 are covered by the conductive shield layer 5. The conductive shield layer 5 is electrically connected to the part of the ground wiring line 10 exposed from the side surfaces of the insulating substrate 6.

The conductive shield layer 5 prevents an unnecessary electromagnetic wave emitted from the semiconductor chip 3 in the sealing resin layer 4 and the wiring layers of the wiring board 2 from leaking out and prevents an electromagnetic wave emitted from an external device from adversely affecting the semiconductor chip 3. The conductive shield layer 5 is preferably made of a metal material layer with low resistivity. The conductive shield layer 5 is made of at least one metal selected from copper, silver, and nickel or an alloy containing at least one of these metals, for instance. A thickness of the conductive shield layer 5 is preferably set based on its resistivity. The thickness of the conductive shield layer 5 is preferably set so that a sheet resistance value obtained by dividing the resistivity of the conductive shield layer 5 by the thickness of the layer, becomes 0.5Ω or less. By setting the sheet resistance value of the conductive shield layer 5 to 0.5Ω or less, it is possible to suppress, with good reproducibility, the leakage of the unnecessary electromagnetic wave from the sealing resin layer 4 and the entrance of the electromagnetic wave emitted from the external device into the sealing resin layer 4.

The unnecessary electromagnetic wave emitted from the semiconductor chip 3 and the like and the electromagnetic wave emitted from the external device are shielded by the conductive shield layer 5 covering the sealing resin layer 4. Therefore, it is possible to suppress the leakage of the unnecessary electromagnetic wave to the outside via the sealing resin layer 4, and the entrance of the electromagnetic wave from the outside into the sealing resin layer 4. There is a possibility that the electromagnetic waves leak or enter also from the side surfaces of the wiring board 2. For this reason, the conductive shield layer 5 preferably covers the whole side surfaces of the wiring board 2. FIG. 2 illustrates a state where the whole side surfaces of the wiring board 2 are covered by the conductive shield layer 5. Consequently, it is possible to effectively suppress the leakage and the entrance of the electromagnetic waves from the side surfaces of the wiring board 2. Although an illustration is omitted in FIG. 2, it is also possible to cover the conductive shield layer 5, according to need, by a protective layer excellent in corrosion resistance and anti-migration property (an iron-based protective layer such as a stainless steel layer, for example).

### (Manufacturing Method of Semiconductor Device)

A manufacturing method of the semiconductor device 1 of the embodiment will be described. First, steps before forming the conductive shield layer 5 are carried out, thereby producing a semiconductor package 20 having no conductive shield layer 5 illustrated in FIG. 3. Specifically, the semiconductor package 20 having no conductive shield layer 5 is produced as an object to be processed in a formation step of the conductive shield layer 5 applying a sputtering method (sputtering deposition step). The semiconductor package 20 having no conductive shield layer 5 is produced in the following manner, for example.

The semiconductor chips 3 are respectively mounted on wiring board regions (2) of a multi-cavity integrated board. The internal connection terminals 7 of the respective wiring board regions (2) and the electrode pads 12 of the semiconductor chips 3 are electrically connected by the bonding wires 13. The plurality of semiconductor chips 3 mounted on the multi-cavity integrated board are collectively resin-sealed. The resin-sealed body including the plurality of semiconductor chips 3 is diced along the wiring board regions (2). Specifically, the resin-sealed body including the integrated board and the sealing resin layer is cut to obtain individual pieces of semiconductor packages 20 at a pre-stage of forming the conductive shield layer 5. FIG. 3 illustrates the semiconductor package 20 in the form of individual piece.

In the formation step of the conductive shield layer 5 (sputtering step), the semiconductor package 20 in the form of individual piece is used as the object to be processed. The plurality of semiconductor packages 20 as the objects are housed in a tray to be sent to the sputtering step, and are subjected to the sputtering step under the state. The tray for the sputtering step has a plurality of housing parts in which the objects are housed. The tray is preferably formed of a heat-resistant resin material such as polyphenylene ether (PPE) and polyphenylene sulfide (PPS), or a high thermal conductivity material such as aluminum and duralumin, for example.

The semiconductor packages 20 are disposed in the plurality of housing parts provided in the tray, so that the upper surface and the side surfaces of each of the sealing resin layers 4 and at least a part of the side surfaces of each of the wiring boards 2 are exposed. On the semiconductor packages 20 housed in the tray, a metal material as a material of forming the conductive shield layer 5 is sputtered. Consequently, the conductive shield layer 5 which covers the upper surface and the side surfaces of the sealing resin layer 4 and at least a part of the side surfaces of the wiring board 2 is formed on each of the semiconductor packages 20 in the form of individual pieces.

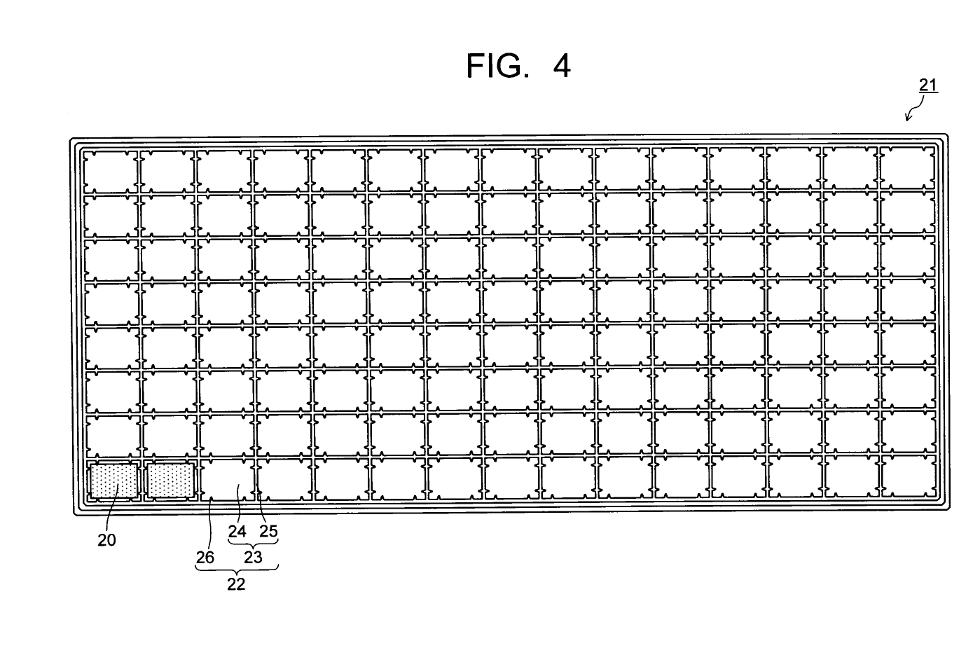

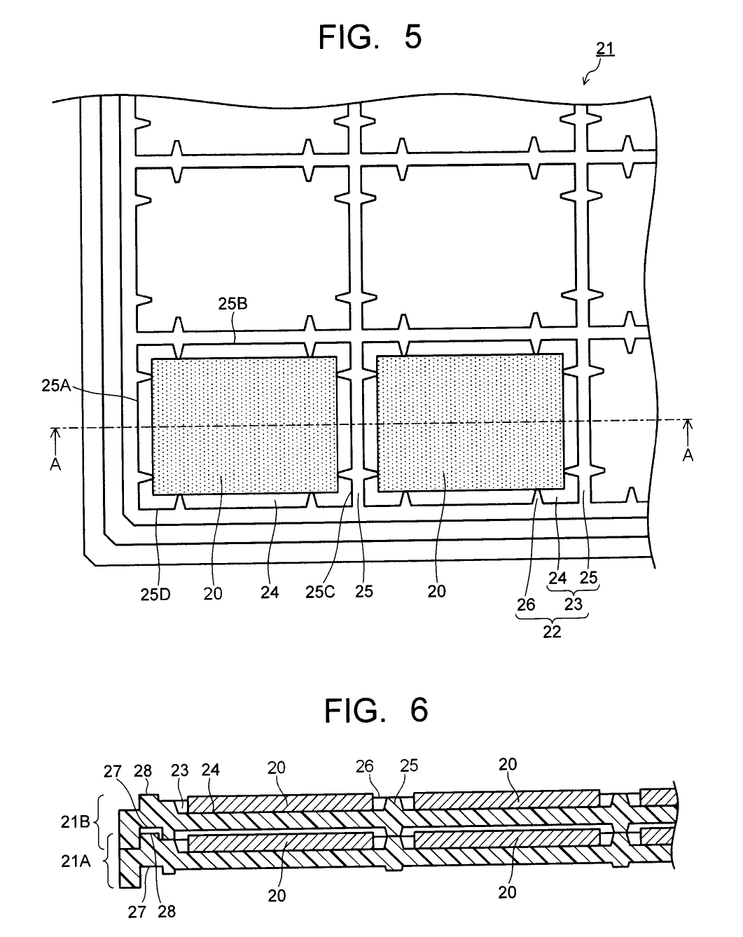

FIG. 4 to FIG. 6 illustrate a first example of a tray 21 for the sputtering step. FIG. 4 is a plan view of the tray 21, FIG. 5 is a plan view illustrating, in an enlarged manner, a part of the tray 21, and FIG. 6 is a sectional view taken along line A-A in FIG. 5. The tray 21 illustrated in these drawings includes a plurality of housing parts 22. FIG. 4 illustrates the tray 21 including 120 housing parts 22. The housing part 22 has a recessed portion 23 in which the semiconductor package 20 as the object is disposed. The recessed portion 23 has a rectangular planar shape (planar shape of the entire recessed portion 23 in a top view) larger than the semiconductor package 20, so that it can house the semiconductor package 20 having a rectangular shape.

The recessed portion 23 is configured with a rectangular bottom surface 24 which is larger than the semiconductor package 20, and a wall portion 25 provided along an outer shape of the bottom surface 24. A periphery of the bottom surface 24 on which the semiconductor package 20 is disposed is surrounded by the wall portion 25. The wall portion 25 has four wall surfaces 25A, 25B, 25C, 25D provided along respective four outer sides of the rectangular bottom surface 24. The shape of the wall portion 25 is not limited to the shape of surrounding the entire periphery of the bottom surface 24, and it may also have a shape of surrounding a part of the periphery of the bottom surface 24. Although it is required to provide the wall portion 25 to each of four sides of the bottom surface 24, the wall portion 25 (wall surfaces 25A to 25D) may also be formed along a part of each of the four outer sides of the bottom surface 24.

A depth of the recessed portion 23 is set to be shallow within a range in which an upper surface of the semiconductor package 20 does not protrude from an upper surface of the tray 21, in order not to hinder the sputtering property of the metal material with respect to the side surfaces of the sealing resin layer 4 and the wiring board 2. When the semiconductor package 20 with a thickness of 1 mm is disposed in the recessed portion 23, the recessed portion 23 whose depth from the upper surface of the tray 21 is 1.2 mm, for example, is applied. Further, a height of the wall portion 25 is preferably set to be lower than a thickness of the semiconductor package 20.

In order to increase the sputtering property of the metal material with respect to the side surfaces of the sealing resin layer 4 and the wiring board 2 of the semiconductor package 20, the bottom surface 24 of the recessed portion 23 has a planar shape larger than the semiconductor package 20. However, when the semiconductor package 20 is disposed by being biased, the formability of the conductive shield layer 5 with respect to a part of the side surfaces of the sealing resin layer 4 and the wiring board 2 is lowered only by the recessed portion 23 having the bottom surface 24 with such a planar shape. Accordingly, ribs 26 are provided, as positioning portions of the semiconductor package 20, to each of the four wall surfaces 25A, 25B, 25C, 25D of the wall portion 25 surrounding the bottom surface 24 of the recessed portion 23. The ribs 26 project toward the inside of the recessed portion 23 from the wall surfaces 25A to 25D. The housing part 22 includes the recessed portion 23 and the ribs 26 provided to project from the four wall surfaces 25A to 25D.

Tips of the ribs 26 provided to the four wall surfaces 25A to 25D are disposed at positions corresponding to an outer shape of the semiconductor package 20. The positioning of the semiconductor package 20 disposed in the recessed portion 23 is performed by the tips of the ribs 26. Distances from respective side surfaces of the sealing resin layer 4 and the wiring board 2 to the wall surfaces 25A to 25D become equal based on the length of projection of the ribs 26. Therefore, it is possible to make the metal material to be favorably deposited on the respective side surfaces of the sealing resin layer 4 and the wiring board 2. The length of projection of the ribs 26 is set by taking a scattering property of sputtered particles in the sputtering step into consideration. For example, in order to make the metal material to be favorably deposited on the whole side surfaces of the wiring board 2, the length of projection of the ribs 26 is preferably set so that each angle of a straight line connecting a lower end portion of the semiconductor package 20 and an upper portion of each of the wall surfaces 25A to 25D (an angle from the bottom surface 24) becomes 50 degrees or less. Further, the wall surfaces 25A to 25D are inclined from their upper portions toward the inside of the recessed portion 23.

Two ribs 26 are formed on each of the wall surfaces 25A to 25D. By positioning each of the respective side surfaces of the semiconductor package 20 by using the plurality of ribs 26, a positioning accuracy of the rectangular semiconductor package 20 can be increased. The tip of the rib 26 is preferably formed to be thin so that a deposition property of the metal material with respect to the side surfaces of the sealing resin layer 4 and the wiring board 2 is not hindered. The rib 26 preferably has a shape in which at least a tip portion thereof is formed in a triangular shape or a round shape. The shape of the tip of the rib 26 is inclined by an amount of draft angle (5 degrees, for example) when injection-molding of the tray 21 made of resin, for example, is performed, but, the shape is set to be substantially vertical. For this reason, the ribs 26 provide excellent positioning accuracy of the respective side surfaces of the semiconductor package 20.

FIG. 6 illustrates a state where a plurality of trays 21 (21A and 21B) are stacked. By taking handleability and conveyance property of the tray 21 housing the semiconductor packages 20 into consideration, the tray 21 has a first engaging portion 27 provided on a lower surface side, and a second engaging portion 28 provided on an upper surface side. The tray 21 illustrated in FIG. 6 has a concave portion as the first engaging portion 27, and a convex portion as the second engaging portion 28. When the plurality of trays 21A and 21B are stacked, the second engaging portion (convex portion) 28 of the tray 21A on the lower stage side and the first engaging portion (concave portion) 27 of the tray 21B on the upper stage side engage with each other. Consequently, a positional displacement of the trays 21 when the plurality of trays 21A and 21B are stacked, and a positional displacement of the semiconductor packages 20 caused by the positional displacement of the trays, can be prevented.

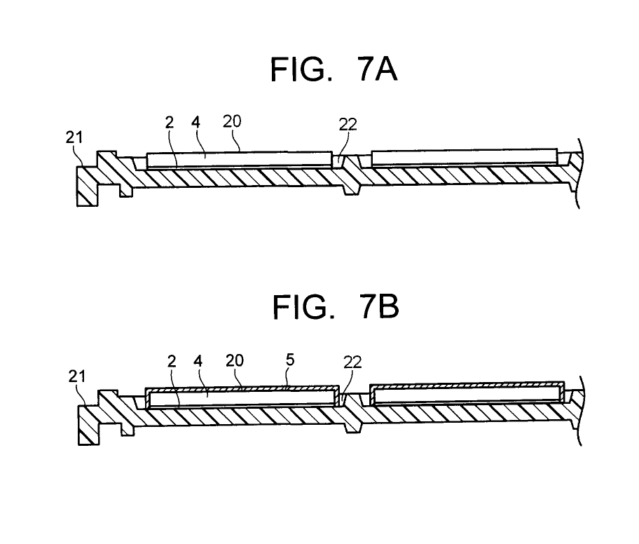

As illustrated in FIG. 7A, each of the semiconductor packages 20 as the objects is sent to the sputtering step in a state of being housed in the housing part 22 of the tray 21, and disposed in a sputtering device whose illustration is omitted. As illustrated in FIG. 7B, by sputtering the metal material in the state of housing the semiconductor packages 20 in the tray 21, the conductive shield layer 5 covering the upper surface and the side surfaces of each of the sealing resin layers 4 and the side surfaces of each of the wiring boards 2 is formed. By conducting the sputtering step in the state of housing the semiconductor packages 20 in the tray 21, it is possible to increase the handleability of the semiconductor packages 20 in the form of individual pieces in the sputtering step. Further, when compared to the sputtering step performed by using the half-cut groove, it is possible to prevent the reduction in workability due to the depth control in the dicing step, and the increase in the number of steps caused by two times of performance of the dicing step.

When the sputtering step is conducted in the state of housing the semiconductor packages 20 in the tray 21, the formability of the conductive shield layer 5 with respect to the side surfaces of the sealing resin layer 4 and the wiring board 2 can be increased depending on the shape of the housing part 22 of the tray 21, concretely, the shape of the recessed portion 23, the rib 26 and the like. Specifically, it is possible to favorably form the conductive shield layer 5 having a thickness required for obtaining the shielding effect, on the side surfaces of the sealing resin layer 4 and the wiring board 2, without increasing a thickness of the conductive shield layer 5 formed on the upper surface of the sealing resin layer 4. Therefore, it is possible to suppress an increase in a cost of material required for the formation of the conductive shield layer 5. According to the manufacturing method of the embodiment, it becomes possible to increase the formability of the conductive shield layer 5 with respect to the semiconductor package 20, and at the same time, it becomes possible to reduce the number of steps of the formation, and the formation cost of the conductive shield layer 5.

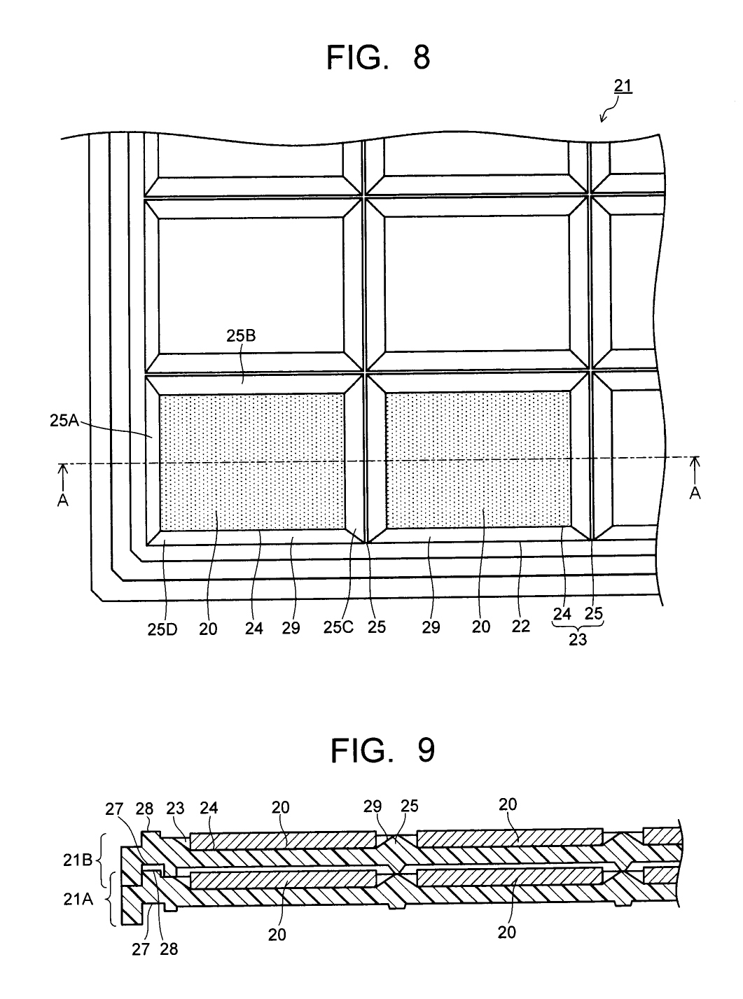

FIG. 8 and FIG. 9 illustrate a second example of the tray 21 for the sputtering step. Parts of the second example same as those of the first example are denoted by the same reference numerals, and a part of explanation thereof will be omitted. FIG. 8 is a plan view illustrating, in an enlarged manner, a part of the tray 21, and FIG. 9 is a sectional view taken along line A-A in FIG. 8. The housing part 22 of the tray 21 illustrated in these drawings includes the recessed portion 23 having a rectangular planar shape larger than the semiconductor package 20, similar to the first example. The recessed portion 23 is configured with the rectangular bottom surface 24, and the wall portion 25 provided along the outer shape of the bottom surface 24. The wall portion 25 may also have a shape of surrounding a part of the periphery of the bottom surface 24, similar to the first example.

The periphery of the bottom surface 24 of the recessed portion 23 is surrounded by the four wall surfaces 25A, 25B, 25C, 25D of the wall portion 25. The semiconductor package 20 is disposed on the bottom surface 24. To each of the four wall surfaces 25A to 25D, an inclined portion 29 is provided as a positioning portion of the semiconductor package 20. The four wall surfaces 25A to 25D are inclined so that the entire shape of the recessed portion 23 in a plan view becomes larger than the bottom surface 24. The entire shape of the recessed portion 23 (planar shape of the entire recessed portion 23 in a top view) is larger than the semiconductor package 20. The inclined portion 29 is provided to be inclined from an upper portion of each of the wall surfaces 25A to 25D toward the inside of the recessed portion 23.

The bottom surface 24 of the recessed portion 23 is set by lower ends of the inclined portions 29, and has a shape corresponding to the outer shape of the semiconductor package 20. The semiconductor package 20 housed in the recessed portion 23 slips down to the bottom surface 24 along the inclined portions 29, thereby performing positioning of the semiconductor package 20. In order to improve the deposition property of the metal material with respect to the side surfaces of the sealing resin layer 4 and the wiring board 2, an angle of the inclined portion 29 is preferably set to be small. When the angle of the inclined portion 29 is lager, it is advantageous regarding the positioning accuracy of the semiconductor package 20. An inclination angle of the inclined portion 29 (angle of an inclined surface from the bottom surface 24) is preferably set to fall within a range of from 35 to 50 degrees.

There is a possibility that the rib 26 in the first example hinders the deposition property of the metal material with respect to the side surfaces of the sealing resin layer 4 and the wiring board 2, but the inclined portion 29 as the positioning portion of the second example does not hinder the deposition property of the metal material with respect to the side surfaces of the sealing resin layer 4 and the wiring board 2. However, as will be described later, there is a possibility that when the semiconductor package 20 after sputtering is taken out from the tray 21, the metal film deposited on the inclined portion 29 remains in the periphery of the conductive shield layer 5 as a burr. In order to suppress the generation of burr, it is preferable that the wall portion 25 is provided along a part of each of four outer sides of the bottom surface 24, and the inclined portion 29 is provided on at least a part of each of the partially-provided wall portions 25. The inclined portion 29 as above will be described in detail in a third example. In order to suppress the generation of burr, it is effective to apply a housing part having a recessed portion formed by providing a level difference on a bottom surface which will be described later.

By conducting the sputtering deposition in the state of housing the semiconductor packages 20 in the tray 21 of the second example, it is possible to increase the handleability of the semiconductor packages 20 in the form of individual pieces in the sputtering step, similar to the first example. When compared to the sputtering step performed by using the half-cut groove, it is possible to prevent the reduction in workability due to the depth control in the dicing step, and the increase in the number of steps caused by the two times of performance of the dicing step. Further, it is possible to increase the formability of the conductive shield layer 5 with respect to the side surfaces of the sealing resin layer 4 and the wiring board 2. Therefore, the increase in the cost of material required for the formation of the conductive shield layer 5 is suppressed. These make it possible not only to increase the formability of the conductive shield layer 5 with respect to the semiconductor package 20, but also to reduce the number of steps of the formation, and the formation cost of the conductive shield layer 5.

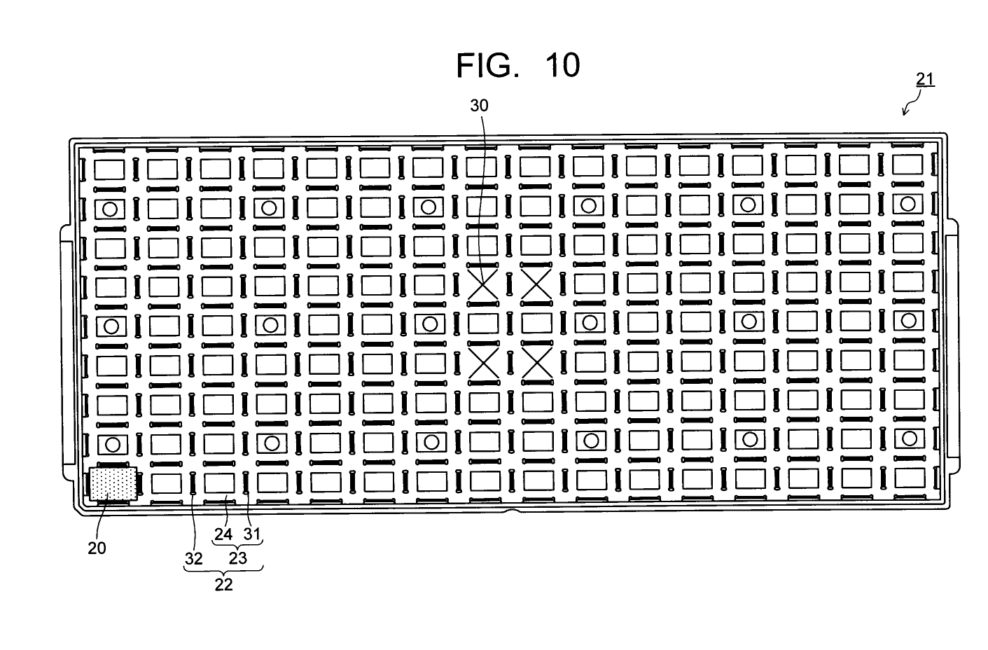

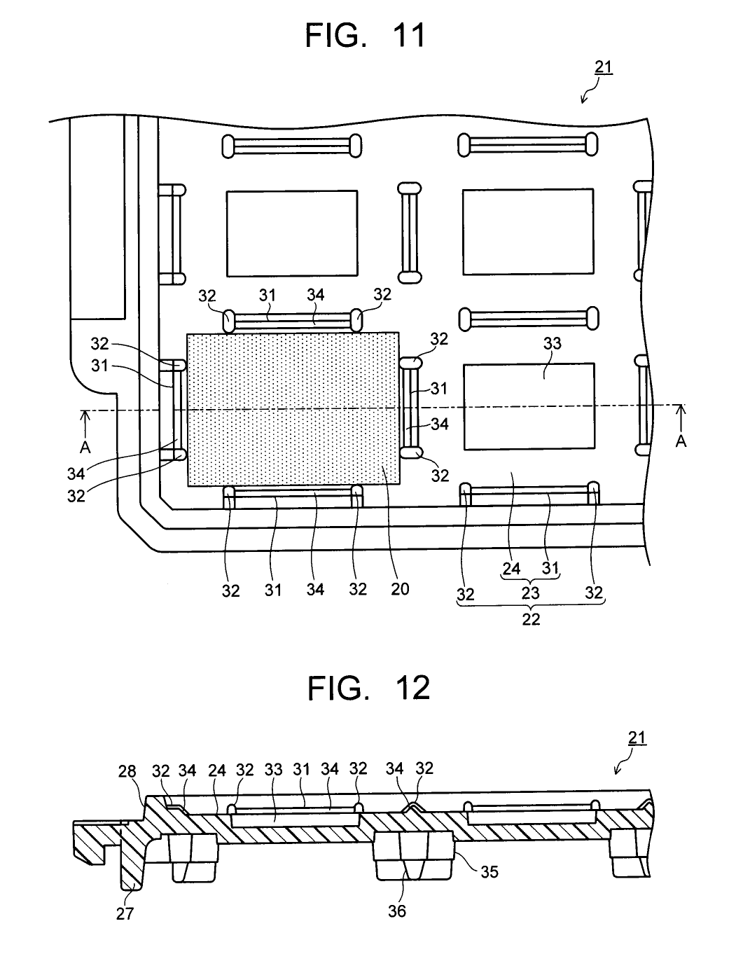

FIG. 10 to FIG. 12 illustrate a third example of the tray 21 for the sputtering step. Parts of the third example same as those of the first and second examples are denoted by the same reference numerals, and a part of explanation thereof will be omitted. FIG. 10 is a plan view of the tray 21, FIG. 11 is a plan view illustrating, in an enlarged manner, a part of the tray 21, and FIG. 12 is a sectional view taken along line A-A in FIG. 11. In FIG. 12, an illustration of the semiconductor package 20 is omitted. The tray 21 illustrated in these drawings includes a plurality of housing parts 22. Out of the plurality of housing parts 22 of the tray 21, four parts in the vicinity of a center are set to suction parts 30 at the time of conveyance. The housing part 22 includes the recessed portion 23 having a rectangular planar shape (planar shape as the entire recessed portion 23) larger than the semiconductor package 20, similar to the first and second examples.

The recessed portion 23 is configured with the bottom surface 24 having a rectangular shape larger than the semiconductor package 20, and wall portions 31 provided along a part of respective four outer sides of the bottom surface 24. The wall surface 24 of the recessed portion 23 is surrounded by the wall portions 31 partially provided to the outer periphery thereof. The wall portions 31 are provided at positions corresponding to the four outer sides of the bottom surface 24, and each of the portions has a length corresponding to a part of each of the outer sides. The wall portions 31 have ribs 32 for performing positioning of the semiconductor package 20. The ribs 32 are provided to both ends of the wall portion 31 having a partial shape. The rib 32 projects from the wall portion 31 toward the inside of the recessed portion 23, and has a shape such that it is inclined from an upper portion of the wall portion 31 toward the inside of the recessed portion 23.

Tips of the ribs 32 are disposed at positions corresponding to the outer shape of the semiconductor package 20. The semiconductor package 20 housed in the recessed portion 23 slips down to the bottom surface 24 of the recessed portion 23 along the ribs 32 having the inclined shape, thereby performing positioning of the semiconductor package 20. The positioning of the semiconductor package 20 is conducted by the tips of the ribs 32. In order to increase the positioning performance of the semiconductor package 20, a corner R of the tip of the rib 32 is set to be as small as possible. When the molding of the tray 21 using the resin material is repeated, there is a possibility that a portion, corresponding to the corner R, of a mold is worn out, resulting in that the corner R is enlarged. With respect to such a point, it is also effective to form a dug-portion in front of the tip of the rib 32. On the bottom surface 24 of the recessed portion 23, a concave portion 33 is provided.

In order to improve the sputtering property of the metal material with respect to the respective side surfaces of the sealing resin layer 4 and the wiring board 2, a width of the rib 32 is narrowed, and a top portion of the rib 32 is set to have a curved surface shape (arc shape or the like). By narrowing the width of the rib 32, sputtered particles are easily deposited on a portion, facing the rib 32, of the side surfaces of the sealing resin layer 4 and the wiring board 2, and a film thickness of that portion becomes thick. In order to prevent such a rib 32 from being broken off or to prevent a warpage after the tray 21 is injection-molded by using a resin material, a convex portion 34 is provided between the two ribs 32. In other words, the wall portion 31 is configured with the ribs 32 at both ends thereof, and the convex portion 34 provided between those ribs 32. The ribs 32 are supported by the convex portion 34.

In order to prevent the convex portion 34 from hindering the deposition property of the metal material, the convex portion 34 has a shape such that a height thereof is lower than that of the rib 32, and a tip thereof is recessed with respect to the tip of the rib 32. The convex portion 34 has an inclined shape whose inclination is relatively smaller than that of the rib 32 in the inclined shape. A concrete height of the convex portion 34 is preferably set to be high within a range in which the height does not exceed a line connecting a lower end portion of one semiconductor package 20 and an upper end portion of an adjacent semiconductor package 20. Even if the height of the convex portion 34 is set to be lower than the range, the deposition property of the metal material is not improved, so that it is preferable to increase the strength and the like of the convex portion 34 within that range.

The tray 21 illustrated in FIG. 12 has a convex portion provided on the lower surface side as the first engaging portion 27, and a concave portion provided on the upper surface side as the second engaging portion 28. Similar to the first and second examples, when the plurality of trays 21 are stacked, the second engaging portion (concave portion) 28 of the tray 21 on the lower stage side and the first engaging portion (convex portion) 27 of the tray 21 on the upper stage side engage with each other. Consequently, a positional displacement and the like of the trays 21 when the plurality of trays 21 are stacked can be prevented.

On the lower surface side of the tray 21 illustrated in FIG. 12, there is further provided a positioning portion 35 of the object. The positioning portion 35 has a tapered portion 36 whose tip is formed in a round shape. In a case such that one end of the semiconductor package 20 housed in the housing part 22 is overlapped with a portion on the wall portion 31, the semiconductor package 20 is pushed by the tapered portion 36 of the positioning portion 35 at the time of stacking the trays 21, thereby disposing the semiconductor package 20 at a proper position in the housing part 22.

By conducting the sputtering deposition in the state of housing the semiconductor packages 20 in the tray 21 of the third example, it is possible to increase the handleability and the like of the semiconductor packages 20 in the form of individual pieces in the sputtering step, similar to the first and second examples. Further, when compared to the sputtering step performed by using the half-cut groove, it is possible to prevent the reduction in workability due to the depth control in the dicing step, and the increase in the number of steps caused by the two times of performance of the dicing step. Further, it is possible to increase the formability of the conductive shield layer 5 with respect to the side surfaces of the sealing resin layer 4 and the wiring board 2. Therefore, it is possible to suppress the increase in the cost of material required for the formation of the conductive shield layer 5. These make it possible not only to increase the formability of the conductive shield layer 5 with respect to the semiconductor package 20, but also to reduce the number of steps of the formation, the formation cost and the like of the conductive shield layer 5.

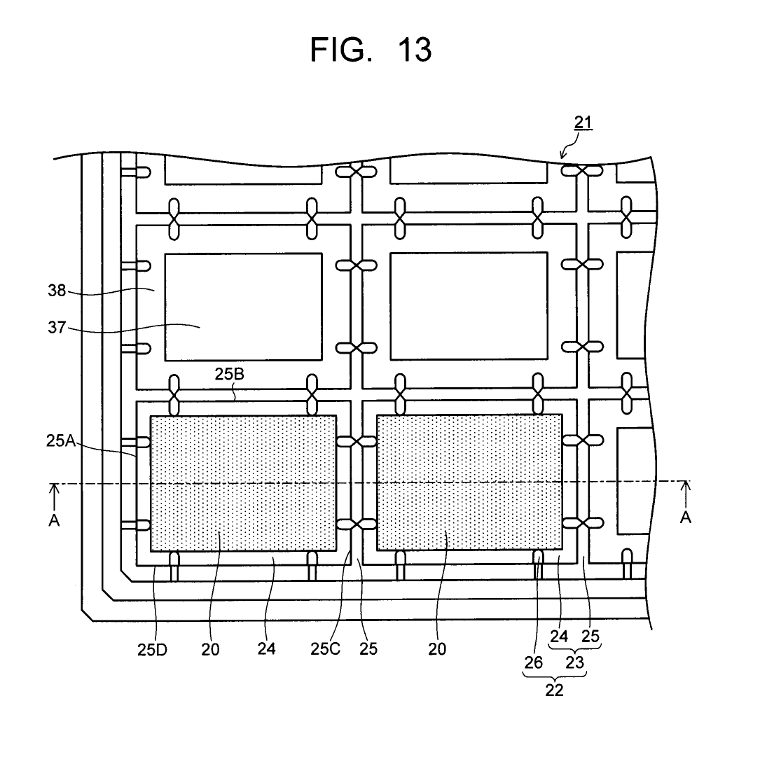

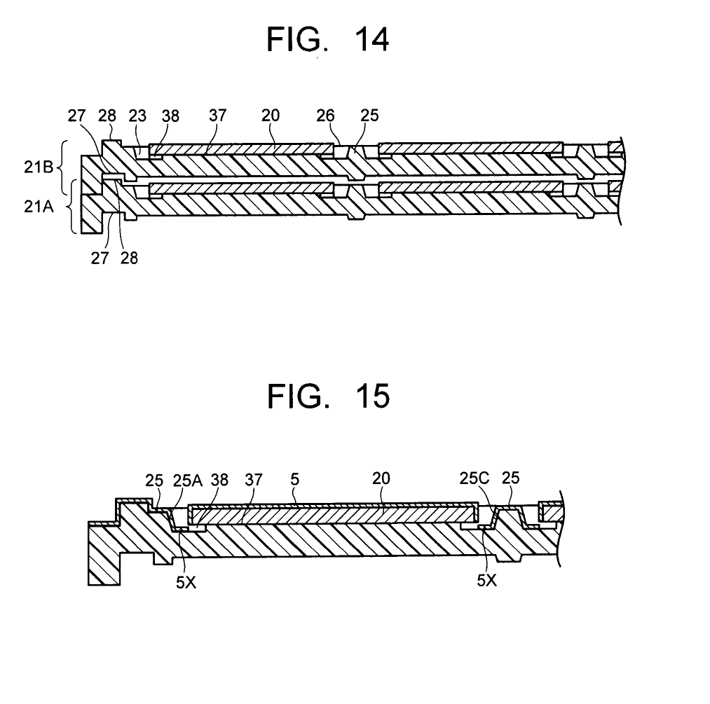

FIG. 13 and FIG. 14 illustrate a fourth example of the tray 21 for the sputtering step. Note that parts of the fourth example same as those of the first to third examples are denoted by the same reference numerals, and a part of explanation thereof will be omitted. FIG. 13 is a plan view illustrating, in an enlarged manner, a part of the tray 21, and FIG. 14 is a sectional view taken along line A-A in FIG. 13. The tray 21 illustrated in these drawings includes a plurality of housing parts 22. Similar to the first example, the housing part 22 includes the recessed portion 23 having a rectangular planar shape larger than the semiconductor package 20. The recessed portion 23 is formed of the rectangular bottom surface 24 larger than the semiconductor package 20, and the wall portion 25 provided along the outer shape of the bottom surface 24.

The periphery of the bottom surface 24 on which the semiconductor package 20 is disposed is surrounded by the wall portion 25. The wall portion 25 has four wall surfaces 25A, 25B, 25C, and 25D provided along respective four outer sides of the rectangular bottom surface 24. A shape of the wall portion 25 is not limited to the shape of surrounding the entire periphery of the bottom surface 24, and it may also be a shape of surrounding a part of the periphery of the bottom surface 24. To each of the wall surfaces 25A to 25D of the wall portion 25 surrounding the bottom surface 24, the ribs 26 for performing positioning of the semiconductor package 20 are provided, similar to the first example. A tip of the rib 26 is formed in a round shape so that the deposition property of the metal material with respect to the side surfaces of the sealing resin layer 4 and the wiring board 2 is not hindered. Further, the rib 26 is preferably inclined, similar to the third example.

In the vicinity of the center of the bottom surface 24 of the recessed portion 23, a supporting portion 37 supporting the semiconductor package 20 is provided so as to project from the bottom surface 24. The recessed portion 23 has a deep hole portion 38 provided at a peripheral portion of the bottom surface 24, and the supporting portion 37 whose depth is shallower than that of the deep hole portion 38. On the bottom surface 24 of the recessed portion 23, there is formed a level difference based on the deep hole portion 38 and the supporting portion 37. Therefore, when the semiconductor package 20 is disposed in the recessed portion 23, the lower surface at the outer peripheral portion of the semiconductor package 20 is in a state of being separated from the bottom surface 24 of the recessed portion 23, concretely, the deep hole portion 38.

The semiconductor packages 20 are subjected to the sputtering step of the metal material in the state of being housed in the tray 21. The lower surface at the outer peripheral portion of each of the semiconductor packages 20 housed in the tray 21 is separated from the bottom surface 24 of the recessed portion 23. When, under this state, the sputtering step is conducted to form the conductive shield layer 5, the conductive shield layer 5 is separated from a metal film 5× formed on the wall surfaces 25A to 25D, as illustrated in FIG. 15. Therefore, it is possible to suppress the generation of burr on the conductive shield layer 5 when the semiconductor package 20 after performing the sputtering deposition is taken out from the tray 21. The other effects are similar to those of the tray 21 in the first example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device, comprising:
preparing a plurality of objects to be processed each having a wiring board, a semiconductor chip mounted on the wiring board, and a sealing resin layer sealing the semiconductor chip;
preparing a tray having a plurality of housing parts;
disposing, in each of the plurality of housing parts of the tray, the object so that an upper surface and side surfaces of the sealing resin layer and at least a part of side surfaces of the wiring board when a surface of the wiring board on which the semiconductor chip is mounted is defined as an upper side are exposed; and
forming a conductive shield layer which covers the upper surface and the side surfaces of the sealing resin layer and at least a part of the side surfaces of the wiring board, by sputtering a metal material on the object disposed in each of the housing parts of the tray.

2. The manufacturing method according to claim 1,
wherein the housing part has a recessed portion having a rectangular planar shape larger than the object, and positioning portions provided in the recessed portion and performing positioning of the object.

3. The manufacturing method according to claim 1,
wherein the housing part includes a recessed portion having a rectangular bottom surface larger than the object and four wall surfaces provided along at least a part of respective four outer sides of the bottom surface, and ribs provided to project from the four wall surfaces, respectively, to position the object disposed in the recessed portion.

4. The manufacturing method according to claim 3,
wherein tips of the ribs are disposed at positions corresponding to an outer shape of the object.

5. The manufacturing method according to claim 3,
wherein the rib has a shape in which an angle of a straight line connecting a lower end portion of the object disposed in the recessed portion and an upper portion of the wall surface becomes 50 degrees or less.

6. The manufacturing method according to claim 3,
wherein a plural number of the ribs are provided to each of the four wall surfaces.

7. The manufacturing method according to claim 3,
wherein the wall surface is inclined from an upper portion thereof toward an inside of the recessed portion.

8. The manufacturing method according to claim 1,
wherein the housing part includes a recessed portion having a rectangular bottom surface and four wall surfaces provided along at least a part of respective four outer sides of the bottom surface, and inclined portions provided by inclining the four wall surfaces to make an entire shape of the recessed portion in a plan view to be larger than the bottom surface, to position the object disposed in the recessed portion.

9. The manufacturing method according to claim 8,
wherein the bottom surface has a shape corresponding to an outer shape of the object.

10. The manufacturing method according to claim 8,
wherein the inclined portion has an inclination angle of from 35 to 50 degrees.

11. The manufacturing method according to claim 1,
wherein the housing part includes a recessed portion having a rectangular bottom surface larger than the object and four wall portions partially provided along a part of respective four outer sides of the bottom surface, and ribs provided at both ends of the four wall portions to respectively project toward an inside of the recessed portion, to position the object disposed in the recessed portion.

12. The manufacturing method according to claim 11,
wherein the rib is inclined from an upper portion thereof toward the inside of the recessed portion.

13. The manufacturing method according to claim 11,
wherein tips of the ribs are disposed at positions corresponding to an outer shape of the object.

14. The manufacturing method according to claim 11,
wherein the wall portion has wall surfaces inclined from an upper portion thereof toward the inside of the recessed portion.

15. The manufacturing method according to claim 1,
wherein the housing part includes a recessed portion having a rectangular bottom surface and four wall surfaces provided along at least a part of respective four outer sides of the bottom surface, a supporting portion provided to project from the bottom surface, and positioning portions for positioning the object, and
wherein the object is disposed on the supporting portion to make a lower surface at an outer peripheral portion of the object to be separated from the bottom surface.

16. The manufacturing method according to claim 15,
wherein the positioning portions have ribs provided to project from the four wall surfaces, respectively.

17. The manufacturing method according to claim 1,
wherein the wiring board has an insulating substrate, and a ground wiring line provided on at least one of a surface and an inner part of the insulating substrate,
wherein a part of the ground wiring line is exposed to a side surface of the insulating substrate, and
wherein the conductive shield layer is formed to be electrically connected to the part of the ground wiring line exposed to the side surface of the insulating substrate.

18. The manufacturing method according to claim 1,
wherein the conductive shield layer is formed to cover the whole side surfaces of the wiring board.

19. The manufacturing method according to claim 1,
wherein the conductive shield layer contains at least one metal selected from the group consisting of copper, silver, and nickel.

20. The manufacturing method according to claim 1,
wherein the tray has a first engaging portion provided on a lower surface side and a second engaging portion provided on an upper surface side, and when a plural number of the trays are stacked, the second engaging portion of the tray on an lower stage engages with the first engaging portion of the tray on an upper stage.
